(19) United States
(12) Patent Application Publication
(10) Pub. No.: US 2005/0116283 A1
(43) Pub. Date: Jun. 2, 2005

(54) Semiconductor device

(75) Inventors: Tetsuya Yoshida, Ora-gun (JP); Tetsuya Okada, Kumagaya-city (JP); Hiroaki Saito, Ota-city (JP); Shigeyuki Murai, Ora-gun (JP); Kikuo Okada, Kodama-gun (JP)

Correspondence Address: Barry E. Bretschneider;Morrison & Foerster LLP, Suite 300, 1650 Tysons Boulevard, McLean, VA, 22102, US

(73) Assignees: Sanyo Electric Co., Ltd., Moriguchi-city (JP); Gifu SANYO Electronics Co., Ltd., Anpachi-gun (JP)

(21) Appl. No.: 10/968,354

(22) Filed: Oct. 20, 2004

(30) Foreign Application Priority Data
Dec. 1, 2003 (JP) 2003-401466

(51) Int. Cl. H01L 29/76

(52) U.S. Cl. 257/327; 257/328; 257/329

(57) ABSTRACT

In conventional semiconductor devices, there observed a problem that cells on the devices may not function uniformly because of voltage drop in a main wiring layer due to a uniform and narrow width of the main wiring layer through which a main current flows. In a semiconductor device of the present invention, a width of one end of a main wire for carrying the main current is formed wider than a width of another end of the main wire. An overall width of the main wire is formed so as to be gradually narrowed from the one end to the another end. In this way, it is possible to reduce a difference in drive voltages between a cell located in the vicinity of an electrode pad for carrying the main current and a cell located in a remote position. Resultantly, it is possible to suppress a voltage drop in the main wire and to achieve uniform operations of cells in an element.

### BACKGROUND OF THE INVENTION

1. Field of the Invention

The present invention relates to an element which has capability of improving ohmic connection of a fixed potential insulated electrode made of polycrystalline silicon and a source region with a metal layer.

2. Description of the Related Art

In a conventional lateral insulated gate transistor, emitter electrodes and gate electrodes are arranged respectively in comb-tooth shapes on a surface of a semiconductor layer. Further, there is disclosed a structure in which values of resistance per unit length in the longitudinal direction of those teeth are mutually equal so as to avoid excessive concentration of on-currents flowing from collector electrodes to emitter electrodes (see Patent Document 1, for example).

Concerning a conventional transistor, there is also disclosed a structure including base electrodes and emitter electrodes which are respectively formed into comb-tooth shapes (see Non-patent Document 1, for example).

An example of a structure of a conventional semiconductor device will be described with reference to FIG. 10A to FIG. 11B. FIG. 10A is a perspective view and FIG. 10B is a top plan view of an element. Meanwhile, FIG. 11A is a cross-sectional view taken along the C-C line in FIG. 10B, and FIG. 11B is a cross-sectional view taken along the D-D line in FIG. 10B.

Firstly, as shown in FIG. 10A, in the conventional semiconductor device includes an n-type semiconductor substrate 51 and an n-type epitaxial layer 52 formed on the n-type semiconductor substrate 51. N-type source regions 54 and trenches 57 are formed mutually orthogonally on the n-type epitaxial layer 52. Further, insulating films 56 are formed to cover inner walls of the trenches 57. Meanwhile, fixed potential insulated electrodes 55 made of highly doped p-type polycrystalline silicon (polysilicon) are formed in the trenches 57. Here, the epitaxial layer 52 is mainly used as a drain region 53. Accordingly, each region in the epitaxial layer 52 sandwiched by the fixed potential insulated electrodes 55 will be hereinafter referred to as a channel region 58.

Now, the fixed potential insulated electrodes 55 are made of the highly doped p-type polysilicon, and the source regions 54 formed on the surface of the channel regions 58 and the fixed potential insulated electrodes 55 are maintained at the same potential value through an Al layer 61. Accordingly, a depletion layer is formed in each channel region 58 owing to the surrounding fixed potential insulated electrodes 55, which is attributable to a work function difference. Further, a potential barrier against conduction electrons is formed in the channel region 58. Therefore, the source region 54 and the drain region 53 are electrically shielded from the beginning.

Next, as shown in FIG. 10B, the fixed potential insulated electrodes 55 are formed into stripes, and both ends of each fixed potential insulated electrode 55 contact the p-type gate regions 59. Further, a gate electrode G is formed on each surface of the gate region 59. Free carriers (positive holes) are supplied from the gate region 59 to the drain region 53 and to the channel region 58. Meanwhile, the channel region 58 surrounded by the fixed potential insulated electrodes 55 constitutes a unit cell.

As shown in FIG. 11A, an arrow H2 is called a channel thickness and an arrow L2 is called a channel length. That is, the channel thickness H2 is equivalent to a gap between the insulating films 56 facing each other in the channel region, and the channel length L2 is equivalent to a distance from a bottom surface of the source region 54 to a bottom surface of the fixed potential insulated electrode 55 along the sidewall of the trenches. Moreover, an Al layer 60 is formed on a rear surface of the substrate 51.

(Patent Document 1) Japanese Unexamined Patent Publication No. Hei 5(1993)-29614 (Page 7 to Page 8, FIG. 1 to FIG. 3)

(Non-patent Document 1) S. M. Sze, “Semiconductor Devices”, Sangyo Tosho, Page 126 to Page 127

As described above, in the conventional semiconductor device, the source region 54 is disposed between the gate regions 59 as illustrated in FIG. 10B. Source electrode wiring layer for carrying a main current includes a plurality of source electrode branch wires ohmically contacting an upper surface of the source region 54, and a single source electrode main wire disposed in the vicinity of a side edge of the epitaxial layer 52. Moreover, a one end of the source electrode main wire is connected to a pad of a source electrode S which is disposed at a corner part on a surface of the epitaxial layer 52, for example. That is, there has been a problem in that the source electrode branch wires exhibit different potential values between a point in the vicinity of the source electrode pad and a point which is remote from the source electrode pad due to wire resistance. Moreover, as a plurality of cells is formed in one element, there has been a difference in gate-source voltages among the cells due to locations of contacts of the source electrode branch wires. Such a voltage difference would cause non-uniform operations in the element.

### SUMMARY OF THE INVENTION

An embodiment of the present invention provides uniform operations of arbitrary cells in an element, by forming a wire width of a source electrode main wire to be wider in the vicinity of a source electrode pad and gradually narrower as the main wire recedes from the source electrode pad, so as to reduce wire resistance.

The present invention has been made in consideration of the foregoing problems. A semiconductor device of the present invention includes a semiconductor layer formed with a plurality of cells, a plurality of current-passing regions and control regions exposed on a surface of the semiconductor layer, a first wiring layer electrically connected to the current-passing regions on the surface, and a current-passing electrode pad electrically connected to the first wiring layer on the surface. Moreover, the first wiring layer includes a first main wire and a plurality of first branch wires extending in one direction from the first main wire. Here, a wire width of the first main wire is wider than a wire width of the first branch wire. Therefore, the semiconductor device of the present invention can suppress excessive concentration of currents on the main wire.

In the semiconductor device of the present invention, one end of the first main wire is connected to the current-passing electrode pad, and a wire width of the one end of the first main wire is wider than a wire width of another end of the first main wire. Therefore, in the semiconductor device of the present invention, it is possible to reduce wire resistance at the first main wire in the vicinity of the current-passing electrode pad and thereby to apply a more uniform voltage to a cell which is disposed in a remote position from the current-passing electrode pad.

Another aspect of a semiconductor device of the present invention includes a semiconductor substrate of a single-conductivity type constituting a drain region, an epitaxial layer of the single-conductivity type laminated on a surface of the substrate, a plurality of trenches formed on a surface of the epitaxial layer in parallel with substantially equal intervals, fixed potential insulated electrodes with insulating films formed on inner walls of the trenches, in which polycrystalline silicon of an opposite-conductivity type is filled so as to cover the insulating films, a source region of the single-conductivity type positioned between the trenches and maintained at an identical potential value to a potential value of the fixed potential insulated electrodes, a gate region isolated from the source region and disposed such that at least a part of the gate region is adjacent to the insulating film, and a channel region positioned between the fixed potential insulated electrodes and at least below the source region. Here, on the surface of the epitaxial layer, a source electrode wiring layer electrically connected to the source region includes the source electrode main wire and a plurality of source electrode branch wires extending in one direction from the source electrode main wire, and a wire width of the source electrode main wire is wider than a wire width of the source electrode branch wire. Therefore, in terms of the source electrode wiring layer of the semiconductor device of the present invention for carrying a main current, it is possible to suppress wire resistance of the source electrode main wire so as to achieve uniform operations of all cells included in a chip.

The semiconductor device of the present invention relates to an improvement in the wire width of the main wire for carrying the main current. Specifically, the wire width of the one end connected to the electrode pad is formed wider than the wire width of the another end. Meanwhile, as an element for carrying a large current exhibits a substantial voltage drop attributable to the wire resistance, it is necessary to suppress such a voltage drop caused by the wiring. Accordingly, in the present invention, the wire width of the one end is formed wider and the wire width is gradually narrowed. In this way, it is possible to suppress a voltage drop in the main wire and thereby to achieve uniform operations of the cells in the element.

Moreover, in the semiconductor device of the present invention, the wire width is increased in terms of only the wire width of the main wire which is configured to carry the main current and is susceptible to the voltage drop attributable to the wiring. By use of this structure, the present invention can secure an actual operation area inside the element and also suppress the voltage drop in the main wire for carrying the main current. In this way, it is possible to secure a desired number of cells and to achieve uniform operations of those cells.

### BRIEF DESCRIPTION OF THE DRAWINGS

FIG. 1A is a perspective view and FIG. 1B is a top plan view for describing a semiconductor device of the present invention.

FIG. 2A is a cross-sectional view and FIG. 2B is another cross-sectional view for describing the semiconductor device of the present invention.

FIG. 3A is an energy band diagram and FIG. 3B is a view explaining a channel region in an off-state for describing the semiconductor device of the present invention.

FIG. 4 is a top plan view for describing a wiring structure of the semiconductor device of the present invention.

FIG. 5A is a top plan view, FIG. 5B is another top plan view, and FIG. 5C is still another top plan view for describing the wiring structure of the semiconductor device of the present invention.

FIG. 6A is a top plan view for describing the wiring structure of the semiconductor device of the present invention, and FIG. 6B is a top plan view for describing a wiring structure of a conventional semiconductor device.

FIG. 7 is a graph for describing voltage drops in the semiconductor device of the present invention and in the conventional semiconductor device.

FIG. 8A is a graph showing a relation between a drive voltage and a main current in the wiring structure of the present invention applied to a semiconductor element of the present invention, and FIG. 8B is a graph showing a relation between a drive voltage and a main current in a conventional wiring structure applied to the semiconductor element of the present invention.

FIG. 9A is a graph showing a relation between a drive voltage and a main current in the wiring structure of the present invention applied to a bipolar transistor element, and FIG. 9B is a graph showing a relation between a drive voltage and a main current in the conventional wiring structure applied to the bipolar transistor element.

FIG. 10A is a perspective view and FIG. 10B is a top plan view for describing a conventional semiconductor device.

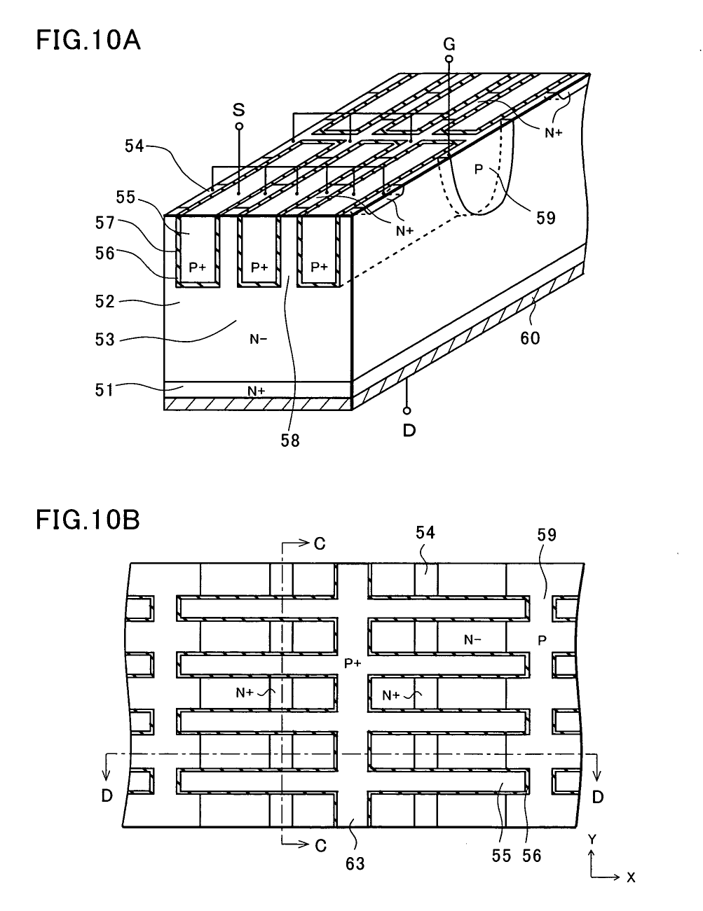

FIG. 11A is a cross-sectional view and FIG. 11B is another cross-sectional view for describing the conventional semiconductor device.

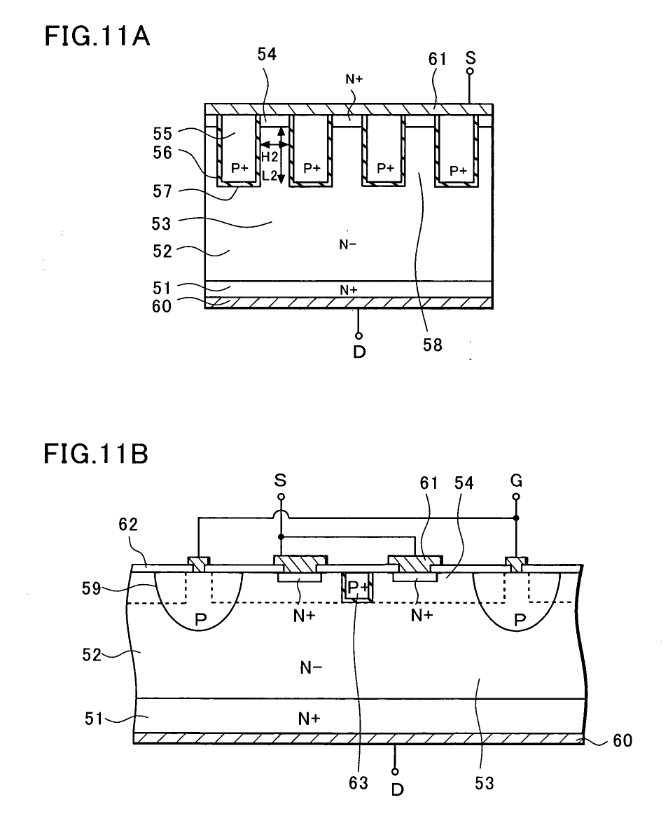

### DETAILED DESCRIPTION OF THE PREFERRED EMBODIMENT

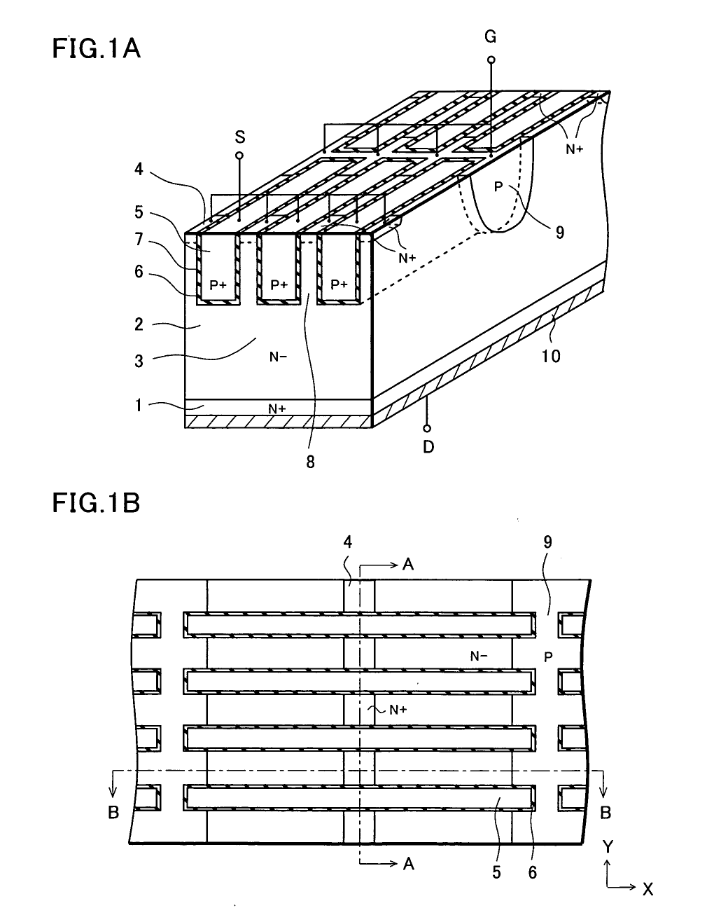

A semiconductor device and a manufacturing method thereof according to an embodiment of the present invention will now be described in detail with reference to FIG. 1A to FIG. 9B.

Firstly, the semiconductor device of the embodiment will be described below with reference to FIG. 1A to FIG. 4.

FIG. 1A is a perspective view showing a structure of the semiconductor device according to the embodiment of the present invention. FIG. 1B is a top view showing the structure of the semiconductor device according to the embodiment of the present invention. As shown in FIG. 1A, on an N-type semiconductor substrate 1, an N-type epitaxial layer 2 is deposited. A plurality of trenches 7 are formed from a surface of the epitaxial layer 2. The trenches 7 are arranged so as to be parallel to each other at even intervals. The substrate 1 is used as a drain lead-out region and the epitaxial layer 2 is mainly used as a drain region 3. Moreover, sidewalls of the trenches 7 are etched to be approximately perpendicular to the surface of the epitaxial layer 2. In addition, insulating films 6 are formed on inner. walls of the trenches 7. Furthermore, in the trenches 7, polysilicon, for example, into which P-type impurities are injected, is deposited. Accordingly, although described in detail later, the polysilicon in the trenches 7 is electrically connected to a source region 4 through aluminum (Al), for example, on the surface of the epitaxial layer 2. Thus, the P-type polysilicon in the trenches 7 is used as a fixed-potential insulated electrode 5 having the same potential as that of a source electrode S. Meanwhile, the epitaxial layer 2 positioned between the plurality of trenches 7 is used as a channel region 8.

As shown in FIG. 1A and FIG. 1B, in this embodiment, a gate region 9 is separated from the source region 4 and a plurality of the gate regions 9 are provided in the epitaxial layer 2 at fixed intervals. As shown in FIG. 1B, between two of the gate regions 9 extending in a Y axis direction, one source region 4 is formed. The source region 4 is formed so as to be equidistant from the respective gate regions 9. The source region 4 is positioned approximately parallel to the gate regions 9 in the Y axis direction. Meanwhile, the trenches 7, which form the fixed-potential insulated electrodes 5, are formed in a direction orthogonal to the source region 4 and the gate regions 9, that is, in a X axis direction. Accordingly, both ends of the trench 7 overlap the respective gate regions 9 at a part of a formation region thereof. Moreover, the trenches 7 are formed at fixed intervals in the Y axis direction.

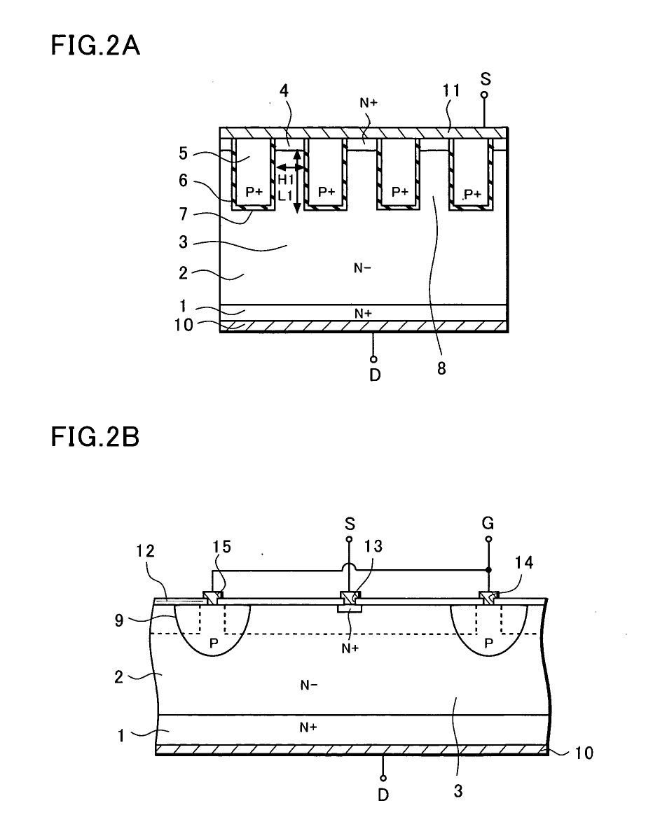

Next, with reference to FIG. 2A and FIG. 2B, description will be given of a cross-sectional structure and operations of the semiconductor device according to the embodiment of the present invention. FIG. 2A is a cross-sectional view along the line A-A in FIG. 1B. FIG. 2B is a cross-sectional view along the line B-B in FIG. 1B.

As shown in FIG. 2A, the channel region 8 is mainly a region which is positioned below the source region 4 and surrounded by the trenches 7. In the channel region 8, the arrow H1 is a channel thickness and the arrow L1 is a channel length. Specifically, the channel thickness H1 means an interval between the insulating films 6 facing each other in the channel region 8 and the channel length L1 means a distance from a bottom surface of the source region 4 to a bottom surface of the fixed-potential insulated electrode 5 along the sidewall of the trench 7. Moreover, an Al layer 10, for example, comes into ohmic contact with a back of the N-type substrate 1 used as the drain lead-out region. A drain electrode D is formed through this Al layer 10.

Meanwhile, on the surface of the epitaxial layer 2, a silicon oxide film 12 as an insulating layer is formed (see FIG. 2B). Accordingly, through a contact region 13 (see FIG. 2B) which is provided in the silicon oxide film 12, an Al layer 11 comes into ohmic contact with the source region 4. Moreover, the Al layer 11 also comes into ohmic contact with the fixed-potential insulated electrode 5 through the contact region 13. According to this structure, as described above, the fixed-potential insulated electrode 5 is applied a source voltage, and the source region 4 and the fixed-potential insulated electrode 5 are maintained to have the same potential. Moreover, the channel region 8 positioned below the source region 4 is also substantially maintained to have the same potential as that of the fixed-potential insulated electrode 5. Note that, the channel region 8 forms a conduction path for a main current, and is capable of cutting-off the main current or controlling the amount of current therethrough. Thus, as long as the conditions are fulfilled, a shape of the fixed-potential insulated electrode 5 included in a unit cell, a shape of the source region 4, and the like are arbitrary.

As shown in FIG. 2B, the silicon oxide film 12 is deposited on the surface of the epitaxial layer 2 including surfaces of the gate regions 9. On the gate region 9, a gate electrode G made of Al, for example, is formed through a contact region 14 provided in the silicon oxide film 12. Note that a broken line in FIG. 2B indicates the presence of the fixed-potential insulated electrode 5. Here, as indicated in FIG. 1A, FIG. 1B, FIG. 2A and FIG. 2B, and thus in the cross-sectional view and the top view, corner portions of the insulating film 6 are drawn to have a square shape. However, those drawings are schematic and, in reality, the corner portions may be round. Specifically, it is widely and generally adopted that the corner portions are formed to be round in order to suppress electric field concentration.

Next, description will be given of operation principles of the semiconductor device according to the embodiment of the present invention.

First, an OFF operation of the semiconductor device will be described. As described above, a current path of the semiconductor device includes: the N-type substrate 1 that is the drain lead-out region; the drain region 3 formed of the N-type epitaxial layer 2; the N-type channel region 8 positioned between the trenches 7; and the N-type source region 4. Specifically, all the regions are formed of N-type regions. Thus, it appears that the OFF operation is impossible when the device is operated in a state where a positive voltage is applied to the drain electrode D and the source electrode S is grounded.

However, as described above, the N-type region including the source region 4 and the channel region 8, and the P-type region that is the fixed-potential insulated electrode 5 are connected to each other through the Al layer 11 and have the same potential. Thus, in the channel region 8 around the fixed-potential insulated electrode 5, due to a work function difference between the P-type polysilicon and the N-type epitaxial layer 2, a depletion layer extends so as to surround the fixed-potential insulated electrode 5. Specifically, by adjusting a width between the trenches 7 which form the fixed-potential insulated electrodes 5, that is, the channel thickness H1, the channel region 8 is filled with the depletion layer extending from the fixed-potential insulated electrodes 5 at both sides. Although described in detail later, the channel region 8 filled with the depletion layer described above becomes a pseudo P-type region.

According to the structure described above, the N-type drain region 3 and the N-type source region 4 can be subjected to PN junction separation by the channel region 8 that is the pseudo P-type region. Specifically, the semiconductor device according to the embodiment of the present invention is set in a cutoff state (OFF state) from the start by forming the pseudo P-type region in the channel region 8. Moreover, when the semiconductor device is OFF, a positive voltage is applied to the drain electrode D, the source electrode S is grounded and the gate electrode G is grounded. In this event, a reverse bias is applied to an interface between the channel region 8 that is the pseudo P-type region and the drain region 3 that is the N-type region. Thus, a depletion layer is formed downward on the page space. Accordingly, a formation state of this depletion layer influences withstand voltage characteristics of the semiconductor device.

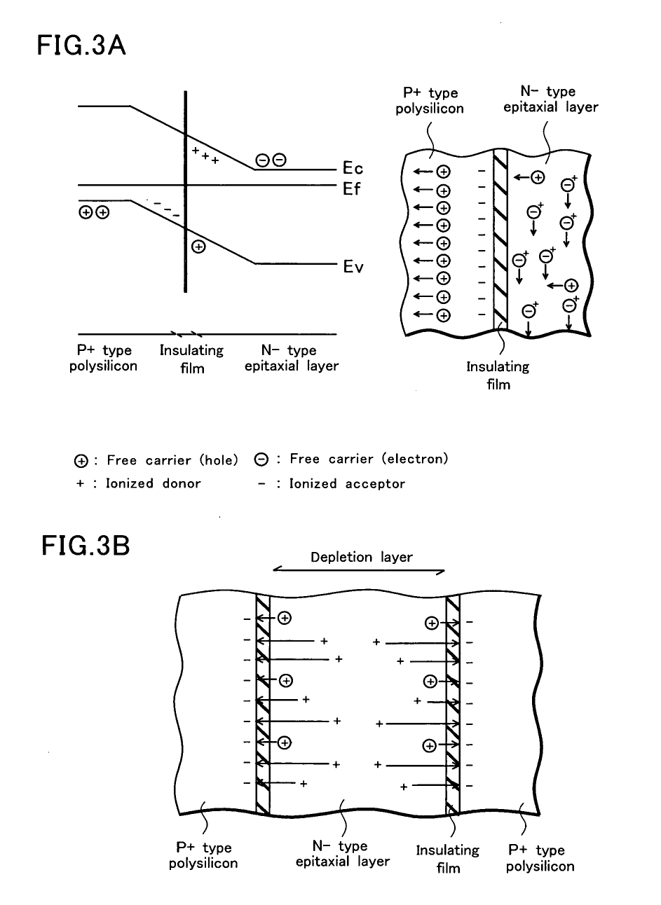

Here, with reference to FIG. 3A and FIG. 3B, the above-described pseudo P-type region will be described below. FIG. 3A shows an energy band diagram in the channel region 8 at the time of OFF. FIG. 3B schematically shows the depletion layer formed in the channel region 8 at the time of OFF. The P-type polysilicon region, that is the fixed-potential insulated electrode 5, and the N-type epitaxial layer 2 region, that is the channel region 8, face each other across the insulating film 6. The both regions are maintained to have the same potential through the Al layer 11 on the surface of the epitaxial layer 2. Accordingly, a depletion layer is formed around the trenches 7 due to the work function difference between the both regions. Consequently, a small number of free carriers (holes) existing in the depletion layer creates a P-type region.

To be more specific, when the P-type polysilicon region and the N-type epitaxial layer 2 region are set to have the same potential through the Al layer 11, the energy band diagram is formed as shown in FIG. 3A. First, in the P-type polysilicon region, a valence band is formed with a negative slope on an interface of the insulating film 6. This state shows that the interface of the insulating film 6 has a high potential energy with respect to the free carriers (holes). Specifically, the free carriers (holes) in the P-type polysilicon region cannot exist on the interface of the insulating film 6 and are pushed to the direction of separating from the insulating film 6. As a result, on the interface of the insulating film 6 in the P-type polysilicon region, negative charges including ionized acceptors are left behind. Accordingly, in the N-type epitaxial layer 2 region, positive charges including ionized donors are required, which are paired up with the negative charges including the ionized acceptors described above. Thus, the channel region 8 is depleted from the interface of the insulating film 6.

However, impurity concentration of the channel region 8 is about 1E14 (/cm³) and a thickness thereof is about 1.0 to 1.4 μm. Thus, the channel region 8 is completely occupied by the depletion layer extending from the fixed-potential insulated electrode 5. In a practical sense, even if the channel region 8 is depleted, it is impossible to secure enough positive charges to match the ionized acceptors. Thus, a small number of free carriers (holes) also exist in the channel region 8. Accordingly, as shown in FIG. 3B, the ionized acceptors in the P-type polysilicon region and the free carriers (holes) or the ionized donors in the N-type epitaxial layer 2 are paired up to form an electric field. As a result, the depletion layer formed from the interface of the insulating film 6 becomes a P-type region and the channel region 8 filled with this depletion layer becomes a P-type region.

Next, description will be given of a state where the operation of the semiconductor device is shifted from OFF to ON. First, a positive voltage is applied to the gate electrode G from the grounded state. In this event, although free carriers (holes) are introduced from the gate region 9, as described above, the free carriers (holes) are attracted to the ionized acceptors and flow into the interface of the insulating film 6. Accordingly, the interface of the insulating film 6 in the channel region 8 is filled with the free carriers (holes). Thus, the ionized acceptors in the P-type polysilicon region and the free carriers (holes) only are paired up to form an electric field. Consequently, free carriers (electrons) come to exist from a farthest area from the insulating film 6 in the channel region 8, that is, a central area of the channel region 8 and a neutral region appears. As a result, the depletion layer in the channel region 8 is reduced, a channel is opened from the central area, the free carriers (electrons) move to the drain region 3 from the source region 4 and a main current flows.

Specifically, the free carriers (holes) spread instantly by using the wall surface of the trench 7 as a passage, the depletion layer extending from the fixed-potential insulated electrode 5 to the channel region 8 is retreated and the channel is opened. Furthermore, if a voltage of a predetermined value or more is applied to the gate electrode G, a PN junction formed by the gate region 9, the channel region 8 and the drain region 3 becomes a forward bias. Thereafter, the free carriers (holes) are directly injected into the channel region 8 and the drain region 3. As a result, a number of the free carriers (holes) distributed in the channel region 8 and the drain region 3 cause conductivity modulation and the main current starts to flow with a low ON-resistance.

Lastly, description will be given of a state where the operation of the semiconductor device is shifted from ON to OFF. In order to turn off the semiconductor device, the potential of the gate electrode G is set in a grounded state (0V) or is set to a negative potential. Accordingly, a large amount of the free carriers (holes) existing in the drain region 3 and the channel region 8 disappears or is removed to the outside of the device through the gate region 9. Thus, the channel region 8 is filled with the depletion layer again and becomes the pseudo P-type region again. Consequently, the withstand voltage is maintained and the main current stops.

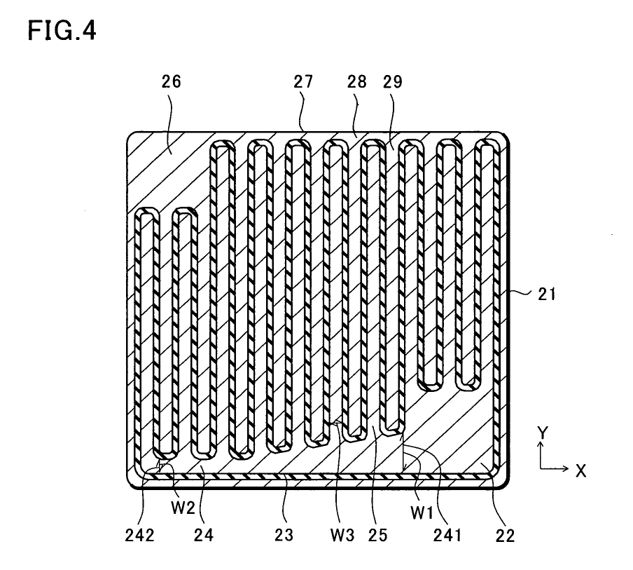

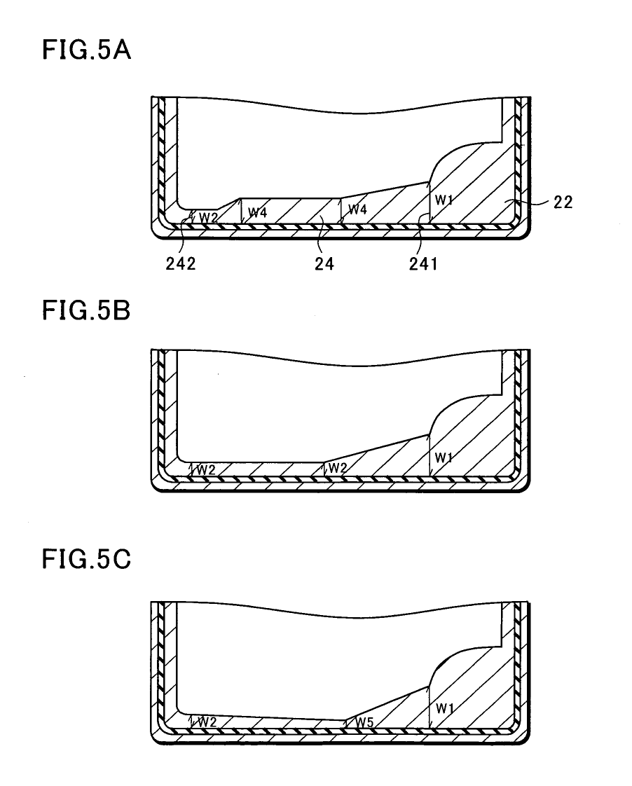

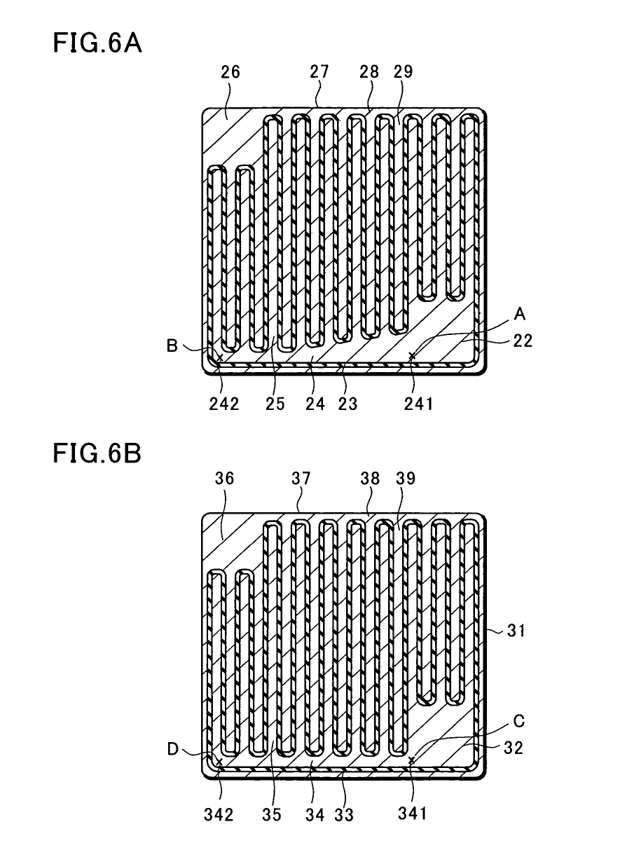

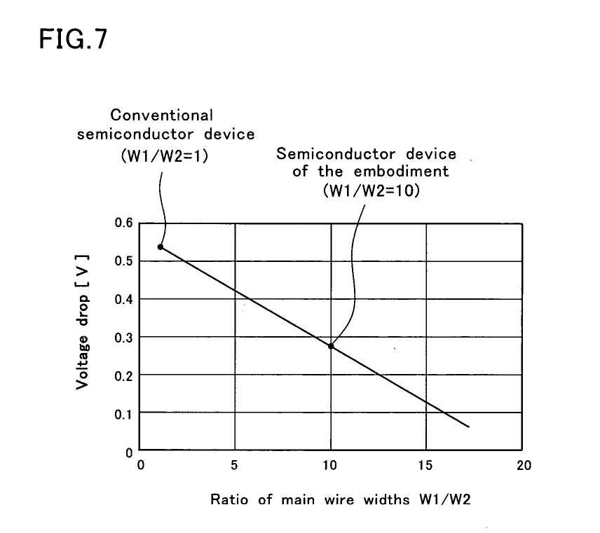

Next, a wiring structure on the surface of the semiconductor element according to the embodiment of the present invention will be described with reference to FIG. 4 to FIG. 7. FIG. 4 is a top plan view showing a source wiring layer and a gate wiring layer of the semiconductor element according to the embodiment of the present invention. FIG. 5A to FIG. 5C are top plan views schematically showing the source wiring layer of the embodiment of the present invention. FIG. 6A is a top plan view schematically showing the wiring structure on an upper surface of the semiconductor element according to the embodiment of the present invention. FIG. 6B is a top plan view schematically showing a wiring structure of an upper surface of a conventional semiconductor element. FIG. 7 is a graph for describing a characteristic of the wiring layer of the embodiment of the present invention.

FIG. 4 illustrates layouts of a source electrode pad 22 made of Al, a source electrode wiring layer 23, a gate electrode pad 26, and a gate electrode wiring layer 27. Note that the source region 4, the fixed potential insulated electrodes 5, the gate regions 9, and the insulating layers are not illustrated therein.

In this embodiment, the source electrode pad 22 is disposed at a corner of a surface which is formed into a square shape. Meanwhile, the source electrode wiring layer 23 includes a source electrode main wire 24 and source electrode branch wires 25. The source electrode main wire 24 is disposed in a region in the vicinity of a side edge on the surface of the epitaxial layer 2. To be more precise, the single source electrode main wire 24 is disposed in the x-axis direction of the drawing in parallel to the side edge on the surface. On the contrary, a plurality of the source electrode branch wires 25 are formed and is extended from the source electrode main wire 24 in the y-axis direction of the drawing. Note that in this embodiment, the source electrode pad 22 and the source electrode main wire 24 are formed on an upper surface of a non-actual operation area disposed in the vicinity of an actual operation area.

Meanwhile, the gate electrode pad 26 is disposed at a corner which is diagonal with the corner where the source electrode pad 22 is disposed. Meanwhile, the gate electrode wiring layer 27 includes a gate electrode main wire 28 and gate electrode branch wires 29. The gate electrode main wire 28 is disposed in a region in the vicinity of another side edge on the surface of the epitaxial layer 2. To be more precise, the single gate electrode main wire 28 is disposed in the x-axis direction of the drawing in parallel to the side edge on the surface. On the contrary, a plurality of gate electrode branch wires 29 are formed and is extended from the gate electrode main wire 28 in the y-axis direction of the drawing. Although it is not illustrated in FIG. 4, a p-type diffused region constituting the gate region 9 surrounds the actual operation area in this embodiment. Accordingly, on the surface of the semiconductor element, the gate electrode wiring layer 27 is disposed so as to surround the source electrode wiring layer 23. Moreover, in this embodiment, the gate electrode pad 26 and the gate electrode main wire 28 are formed on an upper surface of another non-actual operation area disposed in the periphery of the actual operation area.

As illustrated in FIG. 4, in this embodiment, the source electrode main wire 24 and the gate electrode main wire 28 are disposed in the vicinities of mutually opposed side edges on the surface of the epitaxial layer 2, respectively. As described above, the source electrode branch wires 25 and the gate electrode branch wires 29 respectively extend in the y-axis direction as shown in FIG. 4. Further, the source electrode branch wires 25 and the gate electrode branch wires 29 are alternately arranged in comb-tooth shapes, respectively. The source electrode branch wires 25 and the gate electrode branch wires 29 transfer the currents to and from the source electrode main wire 24 and the gate electrode main wire 28, respectively. Meanwhile, the source electrode branch wires 25 and the gate electrode branch wires 29 transfer the currents to and from the source region 4 and the gate region 9, respectively.

In this embodiment, in terms of the source electrode main wire 24 for transferring the main current, a wire width W1 of one end 241 connected to the source electrode pad 22 is formed wider than a wire width W2 of another end 242 located far from the source electrode pad 22. As illustrated therein, the source electrode branch wires 25 extend from the source electrode main wire 24. FIG. 4 shows a case in which seven source electrode branch wires 25 extend from the source electrode main wire 24, for example. Moreover, each of the source electrode branch wires 25 ohmically contacts the source region 4 of each cell for transferring the main current. Here, as illustrated therein, the wire width of the source electrode main wire 24 is formed generally wider than wire widths of the source electrode branch wires 25.

Here, as described previously, the width of the source region 4 is equal to the channel thickness H1, which is determined by a relation with the off operation of the semiconductor device. Moreover, the source regions 4 are arranged with constant widths in the y-axis direction in the actual operation area. As a consequence, a width W3 of each source electrode branch wire 25 is constant as well. Accordingly, there are not significant differences among degrees of voltage drops caused in the seven source electrode branch wires 25. The problem is a voltage drop in the source electrode main wire 24 caused when the current travels from the source electrode pad 22 to the source electrode branch wires 25. The aggregate current to be supplied from one to the seven source electrode branch wires 25 is concentrated on the source electrode main wire 24. Accordingly, an influence of the voltage drop determined by a product of the current and the wire resistance is increased. Then, such a voltage drop causes differences in gate-source voltages among the respective cells and eventually causes non-uniform operations in the chip.

Therefore, in this embodiment, the wire resistance is reduced in the region in the vicinity of the source electrode pad 22 by setting the wire widths of the source electrode main wire 24 as W1>W2. In this way, the respective cells in the actual operation area are operated more uniformly. That is, a voltage drop difference between a cell located in the vicinity of the source electrode pad 22 and a cell located far from the source electrode pad 22, which is attributable to the wire resistance, is suppressed to achieve uniform operations of the respective cells in the semiconductor element 21.

For example, in the semiconductor element 21 shown in FIG. 4, the seven source electrode branch wires 25 extend from the source electrode main wire 24. Moreover, the current to be supplied to the seven source electrode branch wires 25 flows on the one end 241 of the source electrode main wire. In this embodiment, with respect to the wire width W3 of each of the source electrode branch wires 25, it is preferable to provide the wire width W1 of the one end 241 of the source electrode main wire 24 equivalent to W3×7. In this way, it is possible to supply the current more uniformly to the cell located far from the source electrode pad 22, and thereby to achieve the uniform operations of the cells in the semiconductor element 21.

Here, as described above, the source electrode main wire 24 is placed on the upper surface in the non-actual operation area of the semiconductor element 21. Accordingly, the wire width of the source electrode main wire 24 is not always related to the number of the source electrode branch wires 25 connected thereto but is determined based on a relation with an effective layout of the actual operation area of the semiconductor element 21.

As shown in FIG. 4, in this embodiment, the wire widths of the source electrode main wire 24 are determined to satisfy W1>W2, and the overall wire width is formed, narrowing from the one end 241 to the another end 242. However, as described above, the source electrode main wire 24 is related with the layout of the actual operation area. For example, as shown in FIG. 5A, it is possible to design the overall wire width of the source electrode main wire 24 so as to satisfy W1>W2 while providing a constant wire width W4 between the one end 241 and the another end 242. Meanwhile, as shown in FIG. 5B, it is possible to design the overall wire width of the source electrode main wire 24 so as to satisfy W1>W2 while gradually narrowing the wire width from the one end 241 and setting the constant wire width W2 in mid-course. Meanwhile, as shown in FIG. 5C, it is possible to design the overall wire width of the source electrode main wire 24 so as to satisfy W1>W2 gradually narrowing the wire down to a wire width W5 (<W2) in mid-course and then spreading the wire width again. Likewise, it is possible to modify the shape of the wire arbitrarily as long as the wire shape can ensure the uniform operations of the respective cells in the semiconductor element 21.

Note that the description has been made on the case where the wire thickness is constant. However, it is also possible to realize reduction in the wire resistance by changing the wire thickness so as to allow the respective cells in the semiconductor element 21 to be operated with more certain uniformity. In this embodiment, the wire width W1 is about 74 μm, the wire width W2 is about 7.4 μm, and the ratio of W1/W2 is about 10.

Moreover, as shown in FIG. 2A and FIG. 2B, the silicon oxide film 12 is formed on the surface of the semiconductor element 21, i.e. on the surface of the epitaxial layer 2. Further, the source electrode wiring layer 23 and the gate electrode wiring layer 27 ohmically contact the source region 4 and the gate region 9 through the contact regions 13 and 14, respectively.

Now, as shown in FIG. 6A and FIG. 6B, in comparison with the wiring shapes of the semiconductor element of the embodiment and of a conventional semiconductor element, a point A of the semiconductor element of the embodiment corresponds to a point C of the conventional semiconductor element, and a point B of the semiconductor element of the embodiment corresponds to a point D of the conventional semiconductor element.

Here, as shown in FIG. 6B, in a source electrode main wire 34 of the conventional semiconductor element, a one end 341 and another end 342 are formed in the same wire width. Moreover, the same number of the source electrode branch wires 35 is formed in the semiconductor element of the embodiment besides in the conventional source electrode main wire 34. Furthermore, the wire width of the source electrode main wire of this embodiment and the one of the conventional semiconductor element are substantially the same.

FIG. 7 is a graph showing voltage drops in the source electrode main wire. This graph shows a case where a current at 2 A is applied to the semiconductor element of the embodiment, and the source electrode main wire 24 is made of Al of 3 μm thickness, and formed into the dimensions of the wire width W1 at the one end 241 and the wire width W2 at the another end 242. Here, the shape of the source electrode main wire 24 of the semiconductor element of the embodiment is formed into a trapezoid in which the one end 241 constitutes an upper base and the another end 242 constitutes a lower base.

On the contrary, in FIG. 7, a current at 2 A is similarly applied to the conventional semiconductor element, and the source electrode main wire 34 is made of Al of 3 μm thickness and formed into the dimensions of the wire width W2 at the one end 341 and the wire width W2 at the another end 342 at the same time. That is, the shape of the source electrode main wire 34 of the conventional semiconductor element is formed into a rectangle.

As shown in FIG. 7, a ratio of the wire widths between the one end 341 and the another end 342 of the source electrode main wire 34 of the conventional semiconductor element is W2/W2, which is equal to 1, and a voltage drop of about 0.53 V is observed at the point D as compared to the point C. On the contrary, in terms of the source electrode main wire 24 of the semiconductor element of the embodiment, a voltage drop of about 0.42 V is observed at the point B as compared to the point A when the ratio of the wire widths W1/W2 between the one end 241 and the another end 242 is equal to 5. Meanwhile, a voltage drop of about 0.27 V is observed at the point B as compared to the point A when the ratio of the wire widths W1/W2 between the one end 241 and the another end 242 is equal to 10, and a voltage drop of about 0.12 V is observed at the point B as compared to the point A when the ratio of the wire widths W1/W2 between the one end 241 and the another end 242 is equal to 15. In other words, while setting the wire width W2 at the another end 242 of the source electrode main wire 24 as the same width as the conventional structure, it is possible to reduce the voltage drop difference between the point A and the point B by increasing the wire width W1 at the one end 241 connected to the source electrode pad 22.

Here, the wire thickness of the source electrode main wire 24 will be investigated. In this embodiment, the wire thickness of the source electrode wiring layer 23 is about 3 μm. The semiconductor element 21 shown in FIG. 4 is formed into the square 0.13 cm on a side, and the actual operation area is equal to 0.004 cm². Here, the main current at 2 A flows in this actual operation area as described above. Accordingly, the main current flowing in a unit area is equal to 500 A/cm². For this reason, the voltage drop is significant due to the wire resistance. To achieve the uniform operations in the semiconductor element 21, it is appropriate to increase the wire width or the wire thickness.

Wet etching is performed to increase the wire thickness. However, in this case, side etching also progresses simultaneously from side faces of the wiring. Accordingly, it is not possible to form a wire at a constant width on an upper part of the wire which contacts an etching solution for a longer period, and a wire resistance value varies depending on the location. In addition, the use of wet etching complicates fine processing of the wiring layer. Accordingly, the wiring layer cannot bear high integration of the cell region in the semiconductor element 21.

Therefore, in this embodiment, the wire thickness of the source electrode wiring layer 23 is set to about 3 μm and the source electrode wiring layer is formed by dry etching. Alternatively, in order to reduce etching time for the wiring, the source electrode wiring layer 23 is formed by wet etching in the beginning and then by dry etching. In this way, it is possible to solve the above-mentioned problems of the wiring shape, the fine structure, and the like. In other words, there is a limitation when dealing with the voltage drop attributable to the wire resistance by changing the wire thickness. Hence it is appropriate to deal with the voltage drop by changing the wire width. As a result, when the main current has a large value and the voltage drop attributable to the wire resistance affects the uniform operations in the semiconductor element 21 as in this embodiment, it is possible to improve the uniform operations of the semiconductor element 21 by increasing the wire width and thereby reducing the voltage drop.

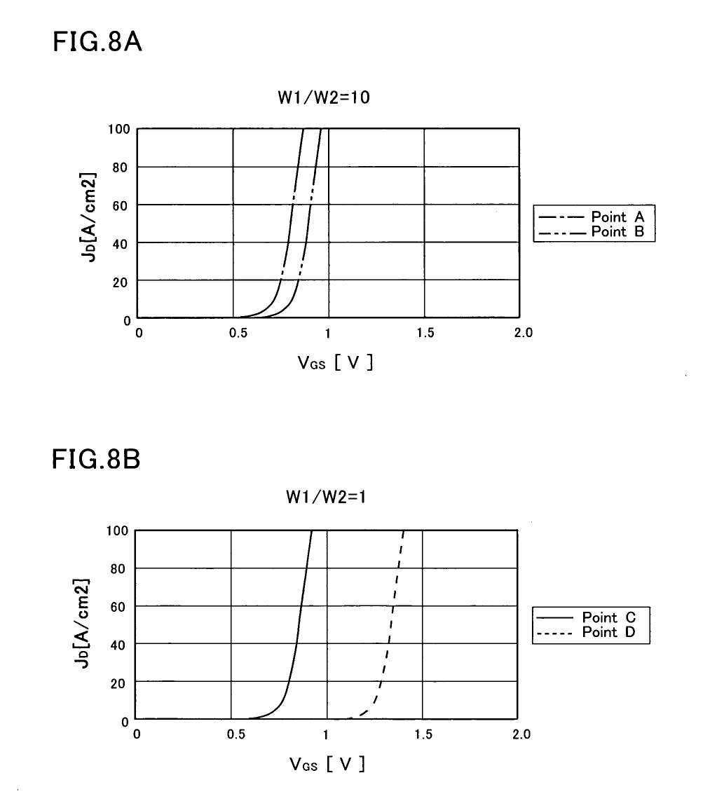

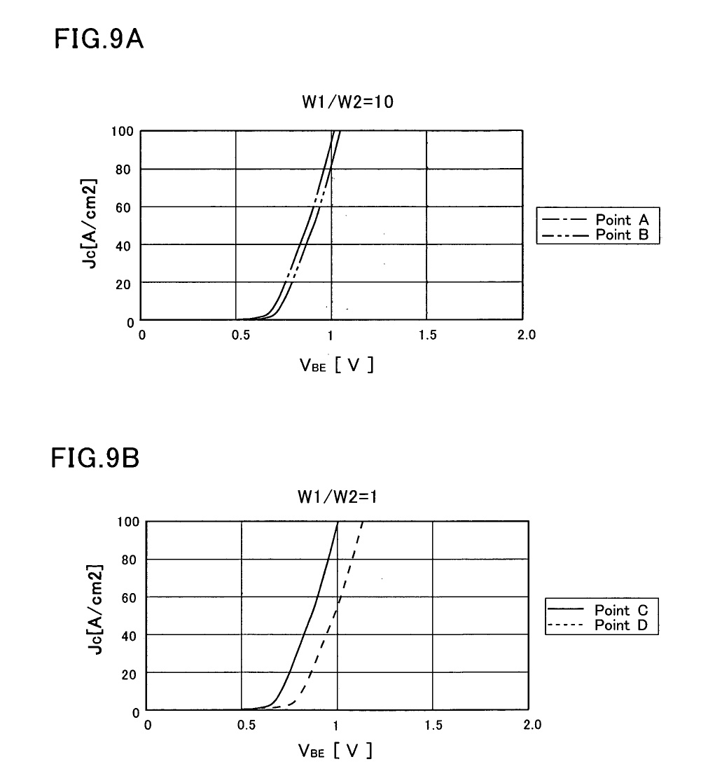

Next, FIG. 8A and FIG. 8B show a relation between a drive voltage and a main current in the semiconductor element of this embodiment. FIG. 8A shows the relation in the wiring structure of this embodiment, and FIG. 8B shows the relation in the conventional wiring structure. FIG. 9A and FIG. 9B show a relation between a drive voltage and a main current in a bipolar transistor element. FIG. 9A shows the relation in the wiring structure of this embodiment, and FIG. 9B shows the relation in the conventional wiring structure. Note that points A to D in FIG. 8A correspond to the points A to D in FIG. 6A and FIG. 6B. Meanwhile, although the bipolar transistor element is not illustrated therein, the data in FIG. 9A and FIG. 9B corresponds to the wiring structures shown in FIG. 6A and FIG. 6B, respectively. In addition, in case of the bipolar transistor, the wiring structure of the source electrode is replaced by a wiring structure of an emitter electrode, and the wiring structure of the gate electrode is replaced by a wiring structure of a base electrode.

Firstly, as shown in FIG. 8B, in case of the conventional wiring structure (when the ratio of the wire widths is equal to 1) of FIG. 6B, a cell in the vicinity of the point C at the one end 341 of the source electrode main wire 34 is driven by application of a gate-source voltage at about 0.6 V. Meanwhile, a cell in the vicinity of the point D at the another end 342 of the source electrode main wire 34 is driven by application of a gate-source voltage at about 1.2 V. That is, in the conventional wiring structure shown in FIG. 6B, the drive voltage is almost doubled between the one end 341 and the another end 342 of the source electrode main wire 34 due to the voltage drop caused by the wire resistance, and the uniform operations are hindered.

On the contrary, as shown in FIG. 8A, in case of the wiring structure of the embodiment of the present invention (when the ratio of the wire widths is equal to 10) of FIG. 6A, a cell in the vicinity of the point A at the one end 241 of the source electrode main wire 24 is driven by application of a gate-source voltage at about 0.6 V. Meanwhile, a cell in the vicinity of the point B at the another end 242 of the source electrode main wire 24 is driven by application of a gate-source voltage at about 0.7 V. That is, in the wiring structure of the embodiment of the present invention shown in FIG. 6A, the voltage drop between the one end 241 and the another end 242 of the source electrode main wire 24 caused by the wire resistance is suppressed. Accordingly, there is little difference in the drive voltages, and the uniform operations can be achieved.

As shown in FIG. 9B, in terms of the bipolar transistor element adopting the conventional wiring structure (when the ratio of the wire widths is equal to 1) of FIG. 6B, a cell in the vicinity of the point C at one end of an emitter electrode main wire is driven by application of a gate-source voltage at about 0.6 V. Meanwhile, a cell in the vicinity of the point D at the another end of the emitter electrode main wire is driven by application of a gate-source voltage at about 0.7 V. That is, in the conventional wiring structure shown in FIG. 6B, the uniform operations between the one end and the another end of the emitter electrode main wire are hindered by the voltage drop attributable to the wire resistance. Nevertheless, the difference in the drive voltages is less than the relevant difference observed in the embodiment shown in FIG. 8A.

Similarly, as shown in FIG. 9A, in terms of the bipolar transistor element adopting the wiring structure of the embodiment of the present invention (when the ratio of the wire widths is equal to 10) of FIG. 6A, a cell in the vicinity of the point A at the one end of the emitter electrode main wire is driven by application of a gate-source voltage at about 0.6 V. Meanwhile, a cell in the vicinity of the point B at the another end of the emitter electrode main wire is driven similarly by application of a gate-source voltage at about 0.6 V. That is, the wiring structure of the embodiment of the present invention shown in FIG. 6A can achieve the uniform operations between the one end and the another end of the emitter electrode main wire because there is substantially no difference in the voltage drop attributable to the wire resistance.

As described above, in comparison with the bipolar transistor element, it is apparent that the effect of the embodiment of the present invention is significant when applied to the element of this embodiment. This is attributable to the fact that the element of this embodiment is a large current density element as compared to the bipolar transistor element. For example, the element of this embodiment is configured to carry the current at about 500 A/cm². On the contrary, the bipolar transistor element is configured to carry the current at about 100 A/cm². In other words, the element of this embodiment is a large current density element and thereby causes a larger voltage drop in the wiring. As a result, the wiring structure of this embodiment exerts a more significant effect therein.

As described above, while the embodiment has been described on the case of dealing with the voltage drop by changing the wire width, the embodiment of the present invention is also applicable to a case of dealing with the voltage drop by changing the wire thickness. In addition, various modifications are possible without departing from the gist of the embodiment of the present invention.

1. A semiconductor device comprising:
a semiconductor layer formed with a plurality of cells;
a plurality of current-passing regions and control regions exposed on a surface of the semiconductor layer;
a first wiring layer electrically connected to the current-passing regions on the surface; and
a current-passing electrode pad electrically connected to the first wiring layer on the surface,
wherein the first wiring layer includes a first main wire and a plurality of first branch wires extending in one direction from the first main wire, and
a wire width of the first main wire is wider than a wire width of the first branch wire.

2. The semiconductor device according to claim 1,
wherein one end of the first main wire is connected to the current-passing electrode pad, and
a wire width of the one end of the first main wire is wider than a wire width of another end of the first main wire.

3. The semiconductor device according to claim 2,
wherein the first main wire extends from the one end to the another end while gradually narrowing the wire width of the first main wire.

4. The semiconductor device according to any of claims 1 to 3,
wherein the semiconductor layer includes an actual operation area formed with the cells and a non-actual operation area, and
the first main wire is located on a surface of the non-actual operation area.

5. The semiconductor device according to claim 4, further comprising:
a second wiring layer electrically connected to the control regions,
wherein the second wiring layer includes a second main wire and a plurality of second branch wires extending in one direction from the second main wire, and
the first branch wires and the second branch wires are alternately arranged.

6. A semiconductor device comprising:
a semiconductor substrate of a single-conductivity type constituting a drain region;
an epitaxial layer of the single-conductivity type laminated on a surface of the substrate;
a plurality of trenches formed on a surface of the epitaxial layer in parallel with substantially equal intervals;
insulating films formed on inner walls of the trenches;
fixed potential insulated electrodes made of polycrystalline silicon of an opposite-conductivity type and filled in the trenches so as to cover the insulating films;
a source region of the single-conductivity type positioned between the trenches and maintained at an identical potential value to a potential value of the fixed potential insulated electrodes;
a gate region isolated from the source region and disposed such that at least a part of the gate region is adjacent to the insulating film; and
a channel region positioned between the fixed potential insulated electrodes and at least below the source region,
wherein, on the surface of the epitaxial layer, a source electrode wiring layer electrically connected to the source region includes a source electrode main wire and a plurality of source electrode branch wires extending in one direction from the source electrode main wire, and
a wire width of the source electrode main wire is wider than a wire width of the source electrode branch wire.

7. The semiconductor device according to claim 6,
wherein one end of the source electrode main wire is connected to a source electrode pad, and
a wire width of the one end of the source electrode main wire is wider than a wire width of another end of the source electrode main wire.

8. The semiconductor device according to claim 7,
wherein the source electrode main wire extends from the one end to the another end while gradually narrowing the wire width of the source electrode main wire.

9. The semiconductor device according to any of claims 6 to 8,
wherein the epitaxial layer includes an actual operation area and a non-actual operation area, and
the source electrode main wire is located on the surface of the epitaxial layer in the non-actual operation area.

10. The semiconductor device according to claim 9,
wherein, on the surface of the epitaxial layer, a gate electrode wiring layer electrically connected to the gate region includes a gate electrode main wire and a plurality of gate electrode branch wires extending in one direction from the gate electrode main wire, and
the source electrode branch wires and the gate electrode branch wires are alternately arranged.
